(19) United States
(12) Patent Application Publication
(10) Pub. No.: US 2018/0040851 A1
(43) Pub. Date: Feb. 8, 2018

(54) DISPLAY DEVICE AND METHOD FOR MANUFACTURING THE SAME

(71) Applicant: Japan Display Inc., Tokyo (JP)

(72) Inventor: Yusuke SASAKI, Tokyo (JP)

(21) Appl. No.: 15/611,334

(22) Filed: Jun. 1, 2017

(30) Foreign Application Priority Data
Aug. 4, 2016 (JP) 2016-153501

(51) Int. Cl. H01L 51/52; H01L 27/32

(52) U.S. Cl. CPC H01L 51/5253; H01L 27/3276; H01L 51/5259; H01L 51/5246; H01L 2227/323

(57) ABSTRACT

A display device includes a first inorganic insulating layer covering a display region; a first organic insulating layer on the first inorganic insulating layer; a second inorganic insulating layer on the first organic insulating layer; a second organic insulating layer on the second inorganic insulating layer; and a third inorganic insulating layer on the second organic insulating layer. The second organic insulating layer contains a compound reactive with moisture; and the first organic insulating layer is thicker than the second organic insulating layer.

### CROSS REFERENCE TO RELATED APPLICATIONS

This application is based upon and claims the benefit of priority from the prior Japanese Patent Application No. 2016-153501, filed on Aug. 4, 2016, the entire contents of which are incorporated herein by reference.

### FIELD

An embodiment of the present invention relates to a display device and a method for manufacturing the same.

### BACKGROUND

As display devices usable for electric appliances and electronic devices, a liquid crystal display device using an electro-optical effect of a liquid crystal material and an organic EL (electroluminescence) display device including an organic electroluminescence (EL) element have been developed. Such a display device includes a display screen formed of a plurality of pixels provided on a substrate. Each of the plurality of pixels of the display device includes a liquid crystal element, an organic electroluminescence element or the like as a display element. In the display device, such pixels arrayed in a display region are driven by a pixel circuit and a driving circuit each including a transistor, and thus a signal is input and a moving image or a still image is displayed.

It is known that in the case where an organic EL element is used as a display element, an organic EL layer is deteriorated by moisture. When the display device is driven by use of such a deteriorated organic EL layer, the luminance may be decreased or a display failure may occur. In order to prevent the organic EL layer from being contaminated with moisture, a sealing film is provided. The sealing film may be formed of a combination of an organic insulating layer and an inorganic insulating layer acting as a barrier layer.

Japanese Laid-Open Patent Publication No. 2010-272270 discloses a display device including an organic insulating layer containing a material that is colored when being reacted with moisture. Such a material is contained in order to detect permeation of moisture into the organic insulating layer.

Japanese Laid-Open Patent Publication No. 2011-138748 discloses a display device including at least one organic insulating layer and at least one barrier film alternately provided in a stacking manner. Such a structure is provided in order to improve the sealing performance against moisture.

### SUMMARY

An embodiment according to the present invention provides a display device including a first inorganic insulating layer covering a display region; a first organic insulating layer on the first inorganic insulating layer; a second inorganic insulating layer on the first organic insulating layer; a second organic insulating layer on the second inorganic insulating layer; and a third inorganic insulating layer on the second organic insulating layer. The second organic insulating layer contains a compound reactive with moisture; and the first organic insulating layer is thicker than the second organic insulating layer.

### BRIEF EXPLANATION OF THE DRAWINGS

FIG. 1A and FIG. 1B are each a plan view showing a structure of a display device in an embodiment according to the present invention, and FIG. 10 is a cross-sectional view showing a structure of the display device in an embodiment according to the present invention;

FIG. 2A, FIG. 2B, FIG. 2C and FIG. 2D are each a cross-sectional view showing a structure of the display device in an embodiment according to the present invention;

FIG. 3 is a cross-sectional view showing a structure of the display device in an embodiment according to the present invention;

FIG. 4 is a cross-sectional view showing a structure of the display device in an embodiment according to the present invention;

FIG. 5 is a cross-sectional view showing a structure of the display device in an embodiment according to the present invention;

FIG. 6 is a cross-sectional view showing a structure of the display device in an embodiment according to the present invention;

FIG. 7 is a cross-sectional view showing a structure of the display device in an embodiment according to the present invention;

FIG. 8 is a cross-sectional view showing a structure of the display device in an embodiment according to the present invention;

FIG. 9 is a cross-sectional view showing a method for manufacturing the display device in an embodiment according to the present invention;

FIG. 10 is a cross-sectional view showing the method for manufacturing the display device in an embodiment according to the present invention;

FIG. 11 is a cross-sectional view showing the method for manufacturing the display device in an embodiment according to the present invention; and

FIG. 12 is a cross-sectional view showing the method for manufacturing the display device in an embodiment according to the present invention.

### DESCRIPTION OF EMBODIMENTS

Hereinafter, embodiments according to the present invention will be described with reference to the drawings. The present invention may be carried out in any of various forms and should not be construed as being limited to any of the following embodiments. In the drawings, components may be shown schematically regarding the width, thickness, shape and the like, instead of being shown in accordance with the actual sizes, for the sake of clearer illustration. The drawings are merely examples and do not limit the interpretations of the present invention in any way. In the specification and the drawings, components that have substantially the same functions as those described before with reference to a previous drawing(s) bear the identical reference signs thereto (or identical numerals with “a”, “b” or the like provided after the numerals), and detailed descriptions thereof may be omitted. The words “first”, “second” or the like provided for components are used merely to distinguish the components from each other, and do not have any further meaning unless otherwise specified.

In the specification and the claims, an expression that a component or a region is “on” another component or region encompasses a case where such a component or region is in direct contact with the another component or region and also a case where such a component is above or below the another component or region, namely, a case where still another component or region is provided between such a component or region and the another component or region, unless otherwise specified. In the following description, the terms “above”, “up” and the like refer to the side on which a second substrate is provided with respect to a first substrate, and the terms “below”, “down” and the like refer to the opposite side.

In this specification, the first substrate at least includes one main surface that is planar. On the one main surface, layers including a semiconductor layer and a conductive layer, and components including a transistor and a display element, are provided. A description provided below regarding a cross-section is made with respect to the one main surface of the first substrate. The terms “up”, “upper layer”, “above” and “upper surface” are used with respect to the one main surface of the first substrate.

A display device including an organic EL element having the above-described moisture detection function may not provide a sufficient level of sealing performance. For an organic insulating layer having the moisture detection function, it is difficult to control the positions of colorants, and thus the moisture detection function may not be provided with a sufficiently high level.

An embodiment according to the present invention provided below discloses a display device having both of a function of quickly detecting moisture permeation into any part of a display region covered with a sealing film and a sealing performance of a sufficiently high level to prevent permeation of moisture into a light emitting element. An embodiment according to the present invention discloses a display device having a high reliability.

### Embodiment 1

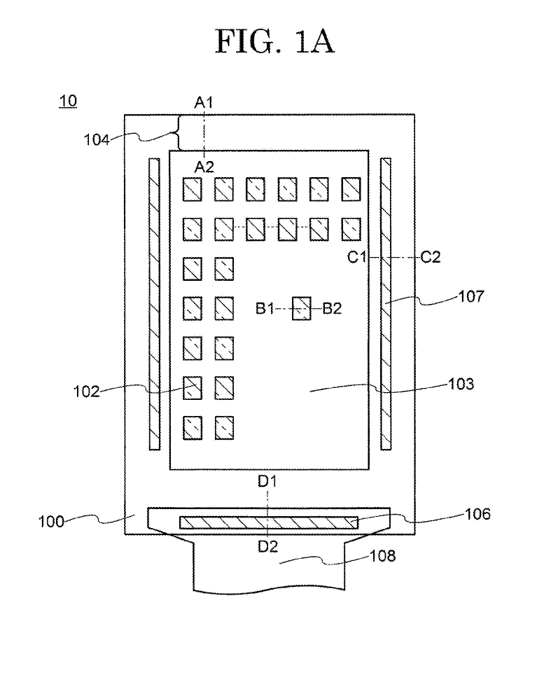

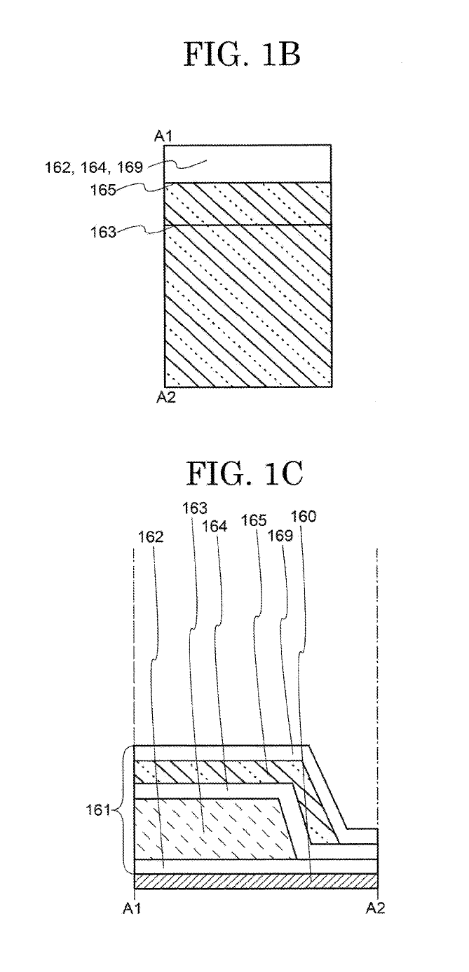

FIG. 1A is a plan view of a display device 10. As shown in FIG. 1A, the display device 10 includes a substrate 100, a display region 103 including pixels 102, a peripheral region 104 provided along a periphery of the display region 103, a driving circuit 106 having a function of a source driver, a driving circuit 107 having a function of a gate driver, and a flexible printed circuit board 108.

The display device 10 is operated as follows. A video signal is input to the display device 10 via the flexible printed circuit board 108, and thus the driving circuit 106 and the driving circuit 107 drive the pixels 102. As a result, a still image or a moving image is displayed in the display region 103.

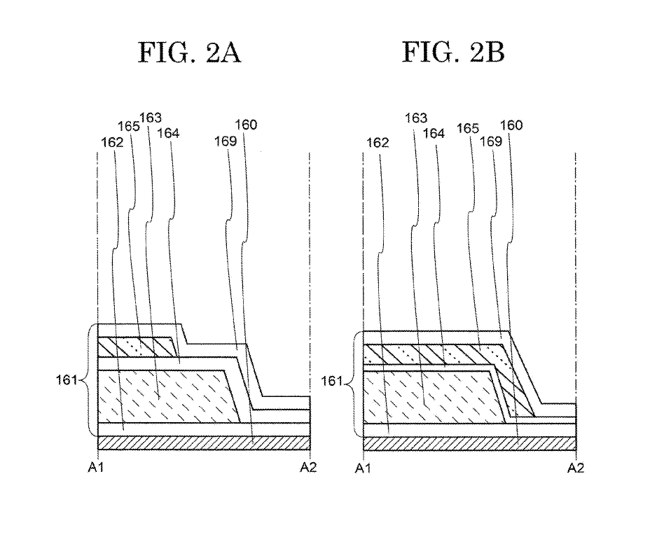

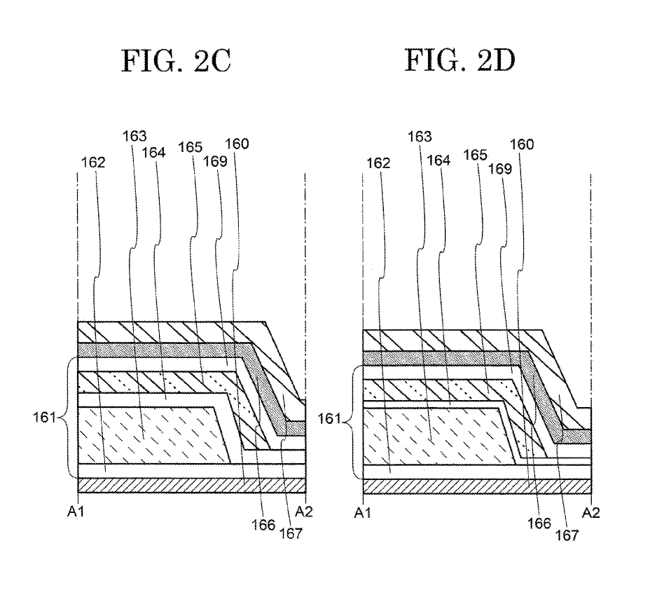

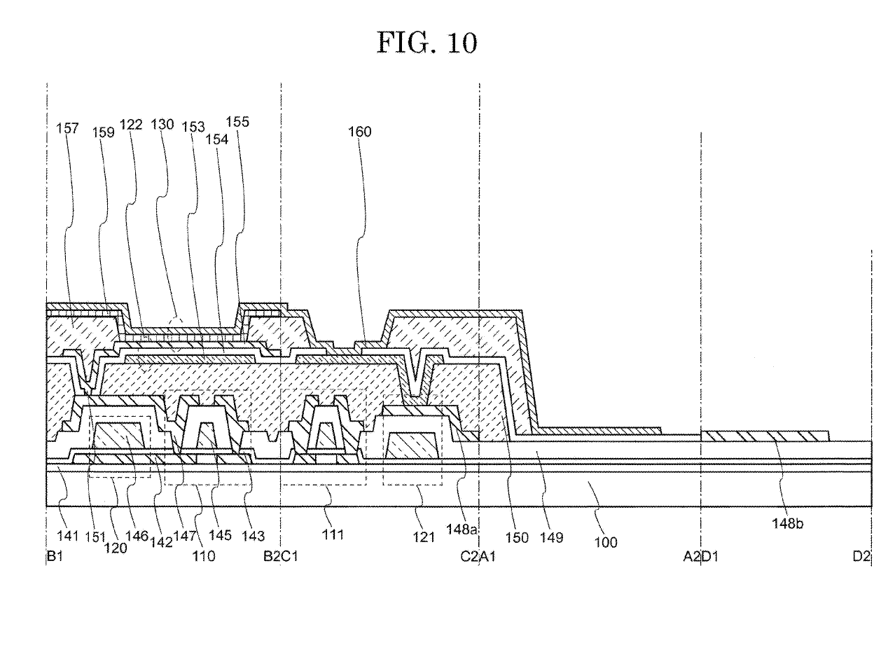

FIG. 1B is an enlarged view of a plan view of a region between A1 and A2 in FIG. 1A corresponding to the peripheral region 104 of the display device 10. FIG. 10 is a cross-sectional view of the display device 10 taken along line A1-A2 in FIG. 1A. FIG. 2A, FIG. 2B, FIG. 2C and FIG. 2D each show a modification of the cross-sectional structure shown in FIG. 10.

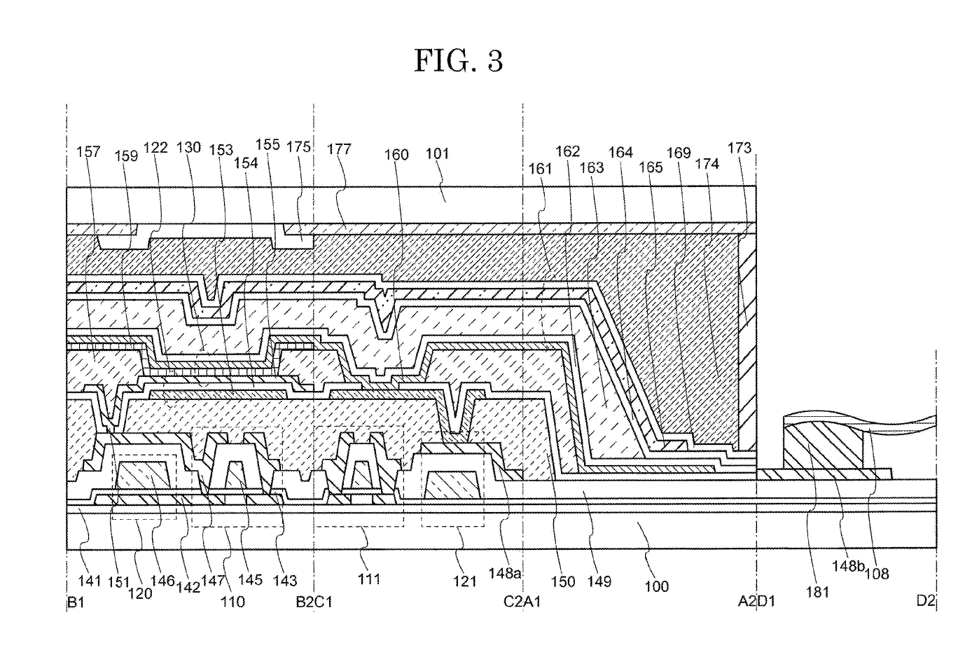

The display device 10 includes a sealing film 161 provided so as to cover the display region 103. The sealing film 161 is provided on a conductive layer 160 acting as an electrode of a display element (or light emitting element) 130 (FIG. 3) described below. As shown in FIG. 10, the sealing film 161 includes an inorganic insulating layer 162, an organic insulating layer 163, an inorganic insulating layer 164, an organic insulating layer 165 and an inorganic insulating layer 169, which are stacked in this order from the side of the display element 130.

The inorganic insulating layer 162, the inorganic insulating layer 164 and the inorganic insulating layer 169 are formed of an inorganic insulating material. More specifically, the inorganic insulating layer 162, the inorganic insulating layer 164 and the inorganic insulating layer 169 may each be formed of at least one selected from aluminum oxide, magnesium oxide, silicon oxide, silicon oxide nitride, silicon nitride oxide, and silicon nitride. The inorganic insulating layer 162, the inorganic insulating layer 164 and the inorganic insulating layer 169 may each have a thickness of several ten nanometers to several micrometers. The inorganic insulating layer 162, the inorganic insulating layer 164 and the inorganic insulating layer 169 are formed of any of the above-described materials so as to have a barrier function against moisture.

The organic insulating layer 163 may be formed of an organic insulating material such as acrylic resin, polyimide resin, epoxy resin or the like. The organic insulating layer 163 preferably has a thickness of 10 μm or greater and less than 100 μm. The organic insulating layer 163 may be a single layer or may be a stack of a plurality of layers.

The organic insulating layer 165 may be formed of any of substantially the same materials as those usable for the organic insulating layer 163. The organic insulating layer 165 further contains, in the organic material, a compound reactive with moisture or oxygen. A compound reactive with moisture or oxygen is, for example, colored as a result of being reacted with moisture or oxygen. A preferable example of a compound that is colored as a result of being reacted with moisture is a colorant. Examples of colorant that is colored as a result of being reacted with moisture include phenolphthalein, thymolphthalein, sodium carbonate and the like. Examples of compound that is colored as a result of being reacted with oxygen include indigocarmine, methylene blue and the like. For example, phenolphthalein and sodium carbonate, when being contained in the organic insulating layer 165 as the colorants, act as follows. When moisture permeates into the organic insulating layer 165, the moisture is reacted with sodium carbonate to become alkaline. At this point, phenolphthalein is reacted with hydroxide ion (OH⁻) in the moisture to be colored pink. The total content of the compounds is preferably about 3% by weight with respect to the total weight of the organic insulating layer 165. The organic insulating layer 165 is preferably thinner than the organic insulating layer 163, and preferably has a thickness of 0.5 μm or greater and less than 10 μm.

As a material reactive with moisture, alkaline metal, alkaline earth metal or the like is usable as well as the colorant.

As described above, the two organic insulating layers are provided and the upper organic insulating layer contains a colorant, so that the sealing performance is improved and, if moisture permeates, occurrence of such an abnormal state is detected easily.

The organic insulating layer 165 is provided as a thin layer, so that the density of the colorant in the organic insulating layer 165 is increased. With such a structure, moisture, if permeating into the sealing film 161, is detected with a high level of precision, and occurrence of such an abnormal state is detected quickly. The thin organic insulating layer 165 allows the organic insulating layer 163, which is located below the thin organic insulating layer 165, to be thicker, which improves the sealing performance.

As shown in FIG. 1B and FIG. 10, it is desirable that in the sealing film 161, edges of the organic insulating layer 163 and the organic insulating layer 165 are located between an edge of the display region 103 and edges of the inorganic insulating layer 162, the inorganic insulating layer 164 and the inorganic insulating layer 169. Alternatively, it is desirable that a region outer to the display region 103 includes a region where the inorganic insulating layer 162 and the inorganic insulating layer 164 are in direct contact with, and stacked on, each other and the inorganic insulating layer 164 and the inorganic insulating layer 169 are in direct contact with, and stacked on, each other (such a region will be referred to as an “inorganic insulating layer stack region”) and that the edge of the organic insulating layer 163 and the edge of the organic insulating layer 165 are located between the display region 103 and the inorganic insulating layer stack region. Namely, it is preferable that the inorganic insulating layer 162 is located below the organic insulating layer 163 and inorganic insulating layer 164 is located above the organic insulating layer 163 and thus the edge of the organic insulating layer 163 is covered with the inorganic insulating layer 164 and, in a region outer to the edge of the organic insulating layer 163, the inorganic insulating layer 162 and the inorganic insulating layer 164 are in contact with each other. In this manner, the edge of the organic insulating layer 163 is located inner to the edges of the inorganic insulating layer 162 and the inorganic insulating layer 164, and the organic insulating layer 163 is held between the inorganic insulating layer 162 on the lower side and the inorganic insulating layer 164 on the upper side. With such a structure, the edge of the organic insulating layer 163 is not exposed to an outer surface of the display device 10. With such a structure, the inorganic insulating layer 162, the inorganic insulating layer 164 and the inorganic insulating layer 169 are in contact with each other, and thus the sealing performance of the sealing film 161 is improved to enhance the moisture blocking effect.

In the sealing film 161, the edges of the organic insulating layer 163 and the organic insulating layer 165 preferably have a mild tapering shape. With such a shape, the area ratio of the surfaces of the organic insulating layer 163 and the organic insulating layer 165 that are covered with the inorganic insulating layer 164 and the inorganic insulating layer 169 is increased, and thus the moisture blocking effect is enhanced. Among the edge of the organic insulating layer 163 and the edge of the organic insulating layer 165, either one may be outer to the other (see FIG. 10 and FIG. 2A).

For these reasons, the display device 10 having the above-described structure has both of a high level of sealing performance and a function of detecting moisture permeation quickly.

The inorganic insulating layer 164 may be as thick as each of the inorganic insulating layer 162 and the inorganic insulating layer 169, or may be thinner than one of, or both of, the inorganic insulating layer 162 and the inorganic insulating layer 169 as shown in FIG. 2B. In the case where the inorganic insulating layer 164 is thinner, the production cost is reduced, and the transmittance of light output from the light emitting element is increased.

The display device 10 may include a moisture absorption layer 166 and a gas releasing layer 167 on the sealing film 161 as shown in FIG. 2C and FIG. 2D.

The moisture absorption layer 166 has a function of absorbing moisture. The moisture absorption layer 166 may be formed of an organic insulating material, an inorganic insulating material, or a composite material of an organic insulating material and an inorganic insulating material. The moisture absorption layer 166 is preferably contain, for example, silicon-containing polymer. Specifically, polysilazane, for example, is usable. The moisture absorption layer 166 prevents moisture from permeating into the inorganic insulating layer 169 and the layers therebelow.

As shown in FIG. 2C and FIG. 2D, the moisture absorption layer 166 and the gas releasing layer 167 may be provided on the inorganic insulating layer 169 of the sealing film 161.

The gas releasing layer 167 has a function of releasing gas present in the layers. The gas releasing layer 167 may contain a thermosetting resin or a thermoplastic resin such as acrylic resin, polyimide resin, epoxy resin or the like.

In the case where, for example, the moisture absorption layer 166 is formed of polysilazane, polysilazane and moisture are reacted with each other to generate ammonia gas. The gas releasing layer 167 allows the ammonia gas to be released therethrough to the outside. Thus, generation of gas bubbles and delamination of layers at the interfaces, which are caused by generation and stay of the gas, are suppressed.

The display device 10 having the above-described structure has a high level of sealing performance and has a function of quickly detecting moisture, if moisture permeates, and also a function of suppressing other defects caused by the permeation of the moisture. Thus, the display device 10 is highly reliable.

The structure, method or the like described in embodiment 1 may be appropriately combined with a structure, method or the like shown in any other embodiment.

### Embodiment 2

Hereinafter, a structure of the display device 10 including components other than those described above will be described with reference to the drawings.

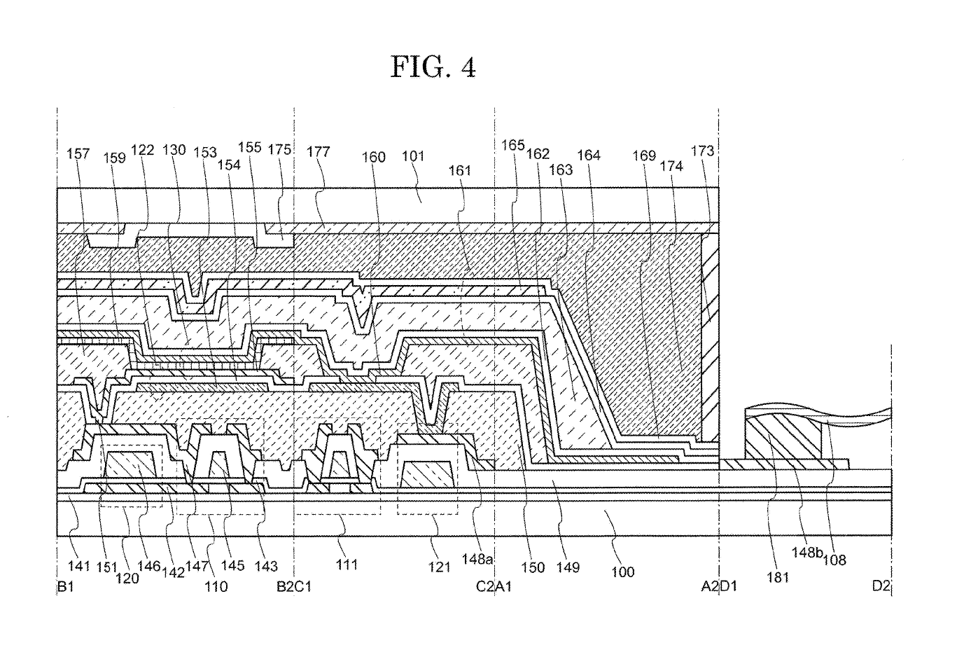

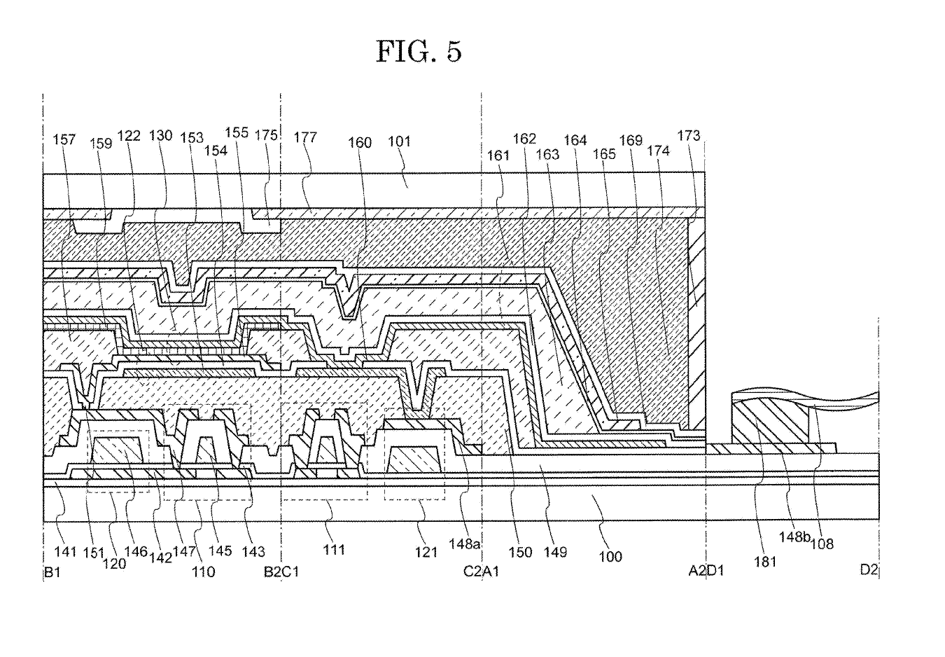

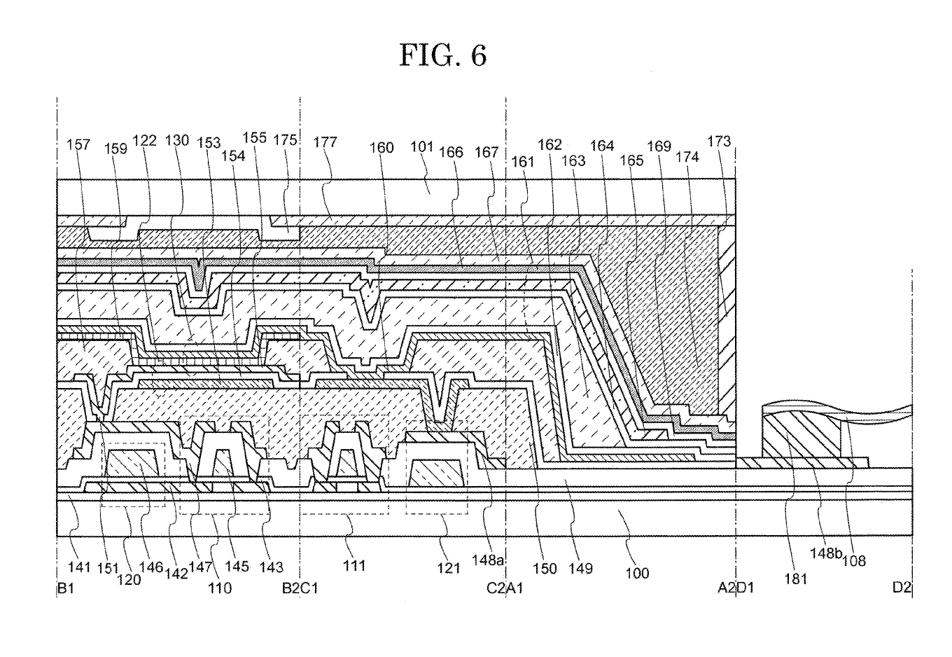

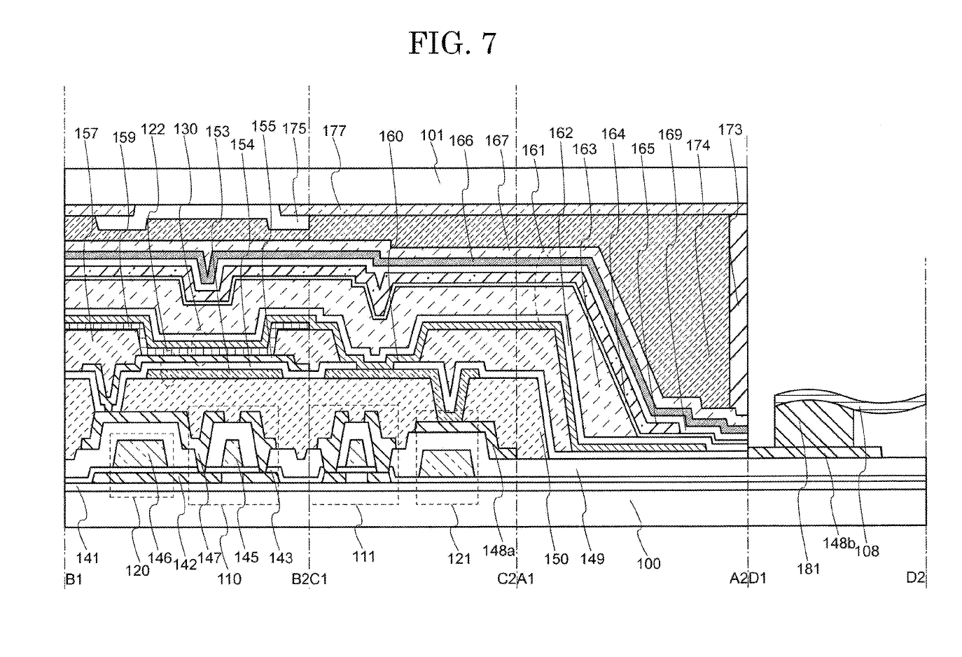

FIG. 3 is a cross-sectional view of the display device 10. More specifically, FIG. 3 shows a cross-section of the peripheral region 104 taken along line A1-A2 in FIG. 1A, a cross-section of a pixel region including one pixel 102 taken along line B1-B2 in FIG. 1A, a cross-section of a driving circuit region including the driving circuit 107 taken along line C1-C2 in FIG. 1A, and a cross-section of a terminal region including the driving circuit 106 taken along line D1-D2 in FIG. 1A. FIG. 3 shows the structure of the display device 10 in the case where the sealing film 161 has the structure shown in FIG. 1C. FIG. 4 shows the structure of the modification of the display device 10, in which the sealing film 161 has the structure shown in FIG. 2A. FIG. 5 shows the structure of the modification of the display device 10, in which the sealing film 161 has the structure shown in FIG. 2B. FIG. 6 shows the structure of the modification of the display device 10, in which the sealing film 161 has the structure shown in FIG. 2C. FIG. 7 shows the structure of the modification of the display device 10, in which the sealing film 161 has the structure shown in FIG. 2D. (Hereinafter, the peripheral region 104 may be referred to as the “peripheral region A1-A2 region”, the pixel region may be referred to as the “pixel region B1-B2”, the driving circuit region may be referred to as the “driving circuit region C1-C2”, and the terminal region may be referred to as the “terminal region D1-D2”.)

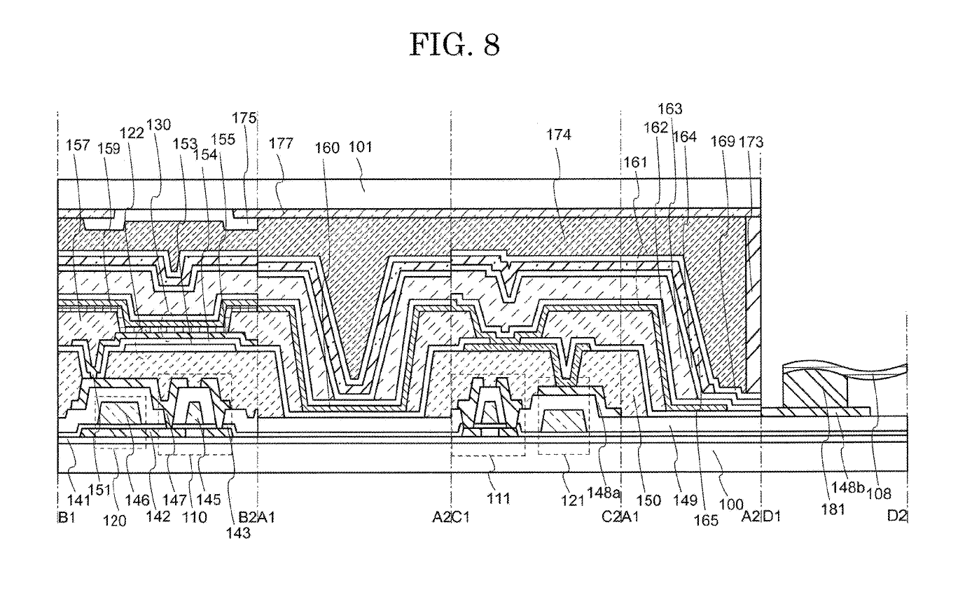

As shown in FIG. 8, the structure of the peripheral region A1-A2 may be provided between the display region 103 including the pixel region B1-B2 and the driving circuit region C1-C2.

A transistor 110 and a transistor 111 each include a semiconductor layer 142, a gate insulating layer 143, a gate electrode layer 145, a source/drain electrode layer 147, and the like. In FIG. 3, the transistors 110 and 111 each have a top gate/top contact structure. The transistors 110 and 111 are not limited to having such a structure, and may each have a bottom gate structure or a bottom contact structure. In the case where the transistors 110 and 111 each have both of an n channel and a p channel, the transistors 110 and 111 may each have a CMOS structure so as to increase the degree of integration and also realize low power consumption.

The first substrate 100 and a second substrate 101 are formed of glass or an organic resin material. A usable organic resin material is, for example, polyimide. The first substrate 100 and the second substrate 101, when being formed of an organic resin material, may each have a thickness of several micrometers to several ten micrometers, so that the display device 10 is a flexible sheet display. The display device 10 may include a glass cover, a protective film or the like provided on each of second surfaces of the first substrate 100 and the second substrate 101 (namely, outer surfaces of the first substrate 100 and the second substrate 101 as seen in a cross-sectional view, more specifically, a lower surface of the first substrate 100 and an upper surface of the second substrate 102). The glass cover, the protective film or the like protects the display device 10 against scratches, breakage or the like.

An insulating layer 141 acts as an underlying layer. The insulating layer 141 may be formed of silicon oxide, silicon oxide nitride, silicon nitride, silicon nitride oxide, gallium oxide, hafnium oxide, yttrium oxide, aluminum oxide, aluminum oxide nitride, or the like. The insulating layer 141 may be a single layer or may be a stack of a plurality of layers. The insulating layer 141 may be formed of any of the above-described materials, so as to suppress impurities, typically, an alkaline metal material, water, hydrogen or the like from being diffused from the first substrate 100 into the semiconductor layer 142.

The semiconductor layer 142 may be formed of silicon, silicon germanium, an oxide semiconductor, an organic semiconductor or the like. Examples of usable type of silicon include amorphous silicon, microcrystalline silicon, polycrystalline silicon, single crystalline silicon, and the like. Usable as an oxide semiconductor is at least one metal material among indium, gallium, zinc, titanium, aluminum, tin, hafnium, neodymium, zirconium, lanthanum, cerium and yttrium. The semiconductor layer 142 may be formed of an oxide semiconductor containing indium, gallium and zinc (IGZO).

The gate insulating layer 143 may be formed of an insulating material containing at least one of aluminum oxide, magnesium oxide, silicon oxide, silicon oxide nitride, silicon nitride oxide, silicon nitride, gallium oxide, zirconium oxide, lanthanum oxide, neodymium oxide, hafnium oxide and tantalum oxide.

The insulating layer 149 and an insulating layer 154 may each be formed of any of the above-described materials usable for the gate insulating layer 143. The insulating layer 149 and the insulating layer 154 may each be a single layer or may be a stack of a plurality of layers.

The gate insulating layer 145 and the source/drain electrode layer 147 may each be formed of a metal element selected from tungsten, aluminum, chromium, copper, titanium, tantalum, molybdenum, nickel, iron, cobalt, indium and zinc, an alloy of any of the above-listed metal materials as one component, an alloy obtained as a result of combining any of the above-listed metal materials, or the like. The gate electrode layer 145 and the source/drain electrode layer 147 may each contain nitrogen, oxygen, hydrogen or the like. The gate insulating layer 145 and the source/drain electrode layer 147 may each be a stack of any of the above-listed materials.

An insulating layer 150 acts as a flattening film. The insulating layer 150 may be formed of an organic insulating material, an inorganic insulating material, or an insulating material containing an organic insulating material and an inorganic insulating material in a stacking manner. The insulating layer 150 may be formed of, for example, a film containing silicon oxide, silicon nitride or the like, a polymer material such as acrylic resin, polyester, polyamide, polyimide, polysiloxane or the like, or a photosensitive resin.

A conductive layer 153 may be formed of any of substantially the same materials as those usable for the gate electrode layer 145 and the source/drain electrode layer 147.

A capacitance element 120 may be provided in a region where a source or drain region of the semiconductor layer 142, and a conductive layer 146 formed of any of substantially the same materials as those usable for the gate electrode layer 145, overlap each other while having the gate insulating layer 143 acting as a dielectric layer therebetween. A capacitance element 121 may be provided in a region where the conductive layer 146 and a conductive layer 148a, which is formed of any of substantially the same materials as those usable for the source/drain electrode layer 147, overlap each other while having the insulating layer 149 acting as a dielectric layer therebetween. A capacitance element 122 may be provided in a region where the conductive layer 153 and a conductive layer 155 overlap each other while having the insulating layer 154 acting as a dielectric layer therebetween.

The light emitting element 130 may include the conductive layer 155, an organic EL layer 159 and the conductive layer 160. In an embodiment according to the present invention, the light emitting element 130 has a so-called top emission structure, in which light emitted by the organic EL layer 159 is output toward the conductive layer 160. The light emitting element 130 is not limited to having a top emission structure, and may have a bottom emission structure.

The organic EL layer 159 contains a light emitting material such as an organic electroluminescence material or the like. The organic EL layer 159 may be formed of a low molecular weight-type or high molecular weight-type organic material. In the case of being formed of a low molecular weight-type material, the organic EL layer 159 may include a light emitting layer containing a light emitting organic material and also include a hole injection layer and an electron injection layer or may further include a hole transfer layer and an electron transfer layer. The hole injection layer and the electron injection layer, or the hole transfer layer and the electron transfer layer, when being included, are provided so as to have the light emitting layer therebetween. For example, the organic EL layer 159 may have a structure in which the light emitting layer is held between the hole injection layer and the electron injection layer. The organic EL layer 159 may further include the hole transfer layer, the electron transfer layer, a hole block layer, an electron block layer and the like as necessary, in addition to the hole injection layer and the electron injection layer.

The conductive layer 155 preferably has a function of a pixel electrode and also has a light reflecting property. The conductive layer 155 may be formed of, for example, a light reflective metal material such as aluminum (Al), silver (Ag) or the like. Alternatively, the conductive layer 155 may have a structure including a transparent conductive layer formed of ITO (indium tin oxide; tin oxide-containing indium oxide) or IZO (indium zinc oxide; indium oxide-zinc oxide) and a light reflective metal layer in a stacking manner.

The conductive layer 160 may be formed of a transparent conductive film such as ITO, IZO or the like, which is light transmissive so as to allow light emitted in the organic EL layer 159 to be transmitted through the conductive layer 160, and is also conductive. The conductive layer 160 may be formed of an alloy of magnesium and silver.

A rib 157 is provided to cover a peripheral portion of the conductive layer 155 and also to form a smooth stepped portion at an edge of the conductive layer 155. The rib 157 may be formed of an organic resin material. The rib 157 may be formed of, for example, acrylic resin, polyimide resin or the like.

A sealing member 173 and a filling member 174 are each formed of an inorganic material, an organic material, or a composite material of an organic material and an inorganic material. The sealing member 173 and the filling member 174 may each be formed of, for example, epoxy resin, acrylic resin, silicone resin, phenol resin, polyimide resin, imide resin, silica gel or the like.

A color filter layer 175 has a function of transmitting light of a specific wavelength range. The color filter layer 175 transmits light of, for example, a red, green, blue or yellow wavelength range. In the case where light emitted from the organic EL layer 159 has different colors on a pixel-by-pixel basis, the color filter layer 175 may not be needed.

A light blocking layer 177 has a function of blocking light. The light blocking layer 177 may be formed of, for example, a resin containing a pigment dispersed therein, a dye-containing resin, an inorganic material such as black chromium or the like, carbon black, a composite oxide containing solid-solution of a plurality of inorganic oxides, or the like.

The flexible printed circuit board 108 may be electrically connected with the conductive layer 148a via an anisotropic conductive film 181.

The structure, method or the like described in embodiment 2 may be appropriately combined with a structure, method or the like shown in any other embodiment.

### Embodiment 3

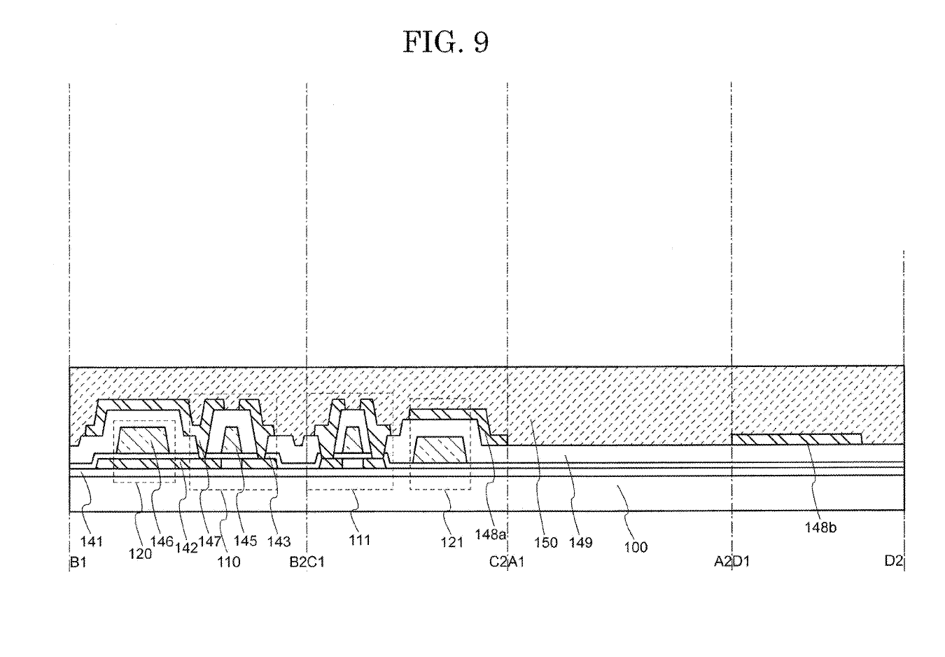

Hereinafter, a method for manufacturing the display device 10 will be described with reference to FIG. 9 to FIG. 12.

As shown in FIG. 9, the following components are formed on a first surface (upper surface as seen in a cross-sectional view) of the first substrate 100: the insulating layer 141, the transistor 110 in the pixel region B1-B2 (the transistor 110 is formed so as to include the semiconductor layer 142, the gate insulating layer 143 and the gate electrode layer 145), the capacitance element 120 (formed to include the conductive layer 146, the gate insulating layer 143, and the source/drain region of the semiconductor layer 142), the transistor 111 in the driving circuit region C1-C2, the capacitance element 121 (formed to include the conductive layer 146, the insulating layer 149, and the conductive layer 148a), the source/drain electrode layer 147, a first terminal layer (conductive layer) 148b in the terminal region D1-D2, the insulating layer 149, and the insulating layer 150. The transistor 110 in the pixel region B1-B2 and the transistor 111 in the driving circuit region C1-C2 have the same structure with each other.

The conductive layer 148a and the conductive layer 148b in the terminal region D1-D2 are formed on the insulating layer 149 and form the same layer as the source/drain electrode layer 147. As the source/drain electrode layer 147, a stack of three layers, specifically, a titanium (Ti) layer, an aluminum (Al) layer and a titanium (Ti) layer provided in this order from the lower side may be formed. Each of these layers may be appropriately formed by photolithography, nanoimprinting, ink-jetting, etching or the like so as to have a predetermined shape.

Referring to FIG. 9, the insulating layer 142 and the insulating layer 149 are each formed by CVD (plasma CVD or thermal CVD), sputtering or the like so as to be a single layer or a stack of a plurality of layers. For example, the insulating layer 149 may be formed by, stacking silicon nitride and silicon oxide.

The insulating layer 150 is formed of an organic insulating material on the insulating layer 149. The organic insulating layer preferably contains a polymer material such as polyester, polyamide, polyimide, polysiloxane or the like. The insulating layer 150 of such an organic insulating material is formed on generally the entirety of the first surface of the first substrate 100 by spin-coating, ink-jetting, laminating, dip-coating, vapor deposition polymerization or the like. The insulating layer 150 is preferably formed to have a thickness of 1 μm or greater. With such a thickness, the insulating layer 150 compensates for concaved and convexed portions provided by the transistor 110 to provide a flat surface above the first substrate 100.

Next, as shown in FIG. 10, the following components are formed on the insulating layer 150 in the pixel region B1-B2: the capacitance element 122 (formed to include the conductive layer 153, the insulating layer 154, and the conductive layer 155), the light emitting element 130 (formed to include the conductive layer 155, the organic EL layer 159, and the conductive layer 160), and the rib 157. Each of the components may be appropriately formed by photolithography, nanoimprinting, ink-jetting, etching or the like so as to have a predetermined shape.

The conductive layer 153 and the conductive layer 155 may be formed by sputtering, vapor deposition, plating or the like to have a thickness of several ten nanometers to several hundred nanometers. For example, the conductive layer 153 may be formed by stacking molybdenum, aluminum and molybdenum by use of sputtering. The conductive layer 155 may be formed by, for example, stacking ITO, silver and ITO by use of sputtering.

The insulating layer 154 may be formed of CVD (plasma DVD or thermal CVD), spin-coating, printing or the like. For example, the insulating layer 154 may be formed of silicon nitride by plasma CVD.

The rib 157 is formed to have an opening exposing an upper surface of the conductive layer 155. An edge of the opening of the rib 157 preferably has a smooth tapering shape. This improves the step coverage. The rib 157 may be formed so as not to be on an upper surface of the conductive layer 148b in the terminal region D1-D2, or may be formed to have an opening exposing the upper surface of the conductive layer 148b. The rib 157 may be formed to have a thickness of several micrometers. The rib 157 may be formed of polyimide by spin-coating.

The organic EL layer 159 is preferably formed to at least overlap the conductive layer 155. The organic EL layer 159 is formed by, for example, vacuum vapor deposition, printing, spin-coating or the like. In the case of being formed by vacuum vapor deposition, the organic EL layer 159 is preferably formed by use of a shadow mask so as not to be in the terminal region D1-D2. The organic EL layer 159 may be formed of different materials among pixels adjacent to each other, or may be formed of the same material in all the pixels. In the case where the organic EL layer 159 outputting white light is formed so as to be included in all the pixels, the color filter 175 or the like may be used, so that light of different colors is output from different pixels.

After the organic EL layer 159 is formed, the conductive layer 160 is formed. The conductive layer 160 is formed of a light transmissive conductive material by sputtering. In the case where, for example, the light emitting element 130 is of a top emission type, by which light is output from the conductive layer 160, the conductive layer 160 preferably has a uniform thickness.

The conductive layer 160 may be formed by vacuum vapor deposition or sputtering. The conductive layer 160 may not be formed in the terminal region D1-D2, or may be removed from the terminal region D1-D2 after being formed. The conductive layer 160 may be formed of IZO by sputtering. Alternatively, the conductive layer 160 may be formed of an alloy of magnesium and silver.

Next, the sealing film 161 is formed.

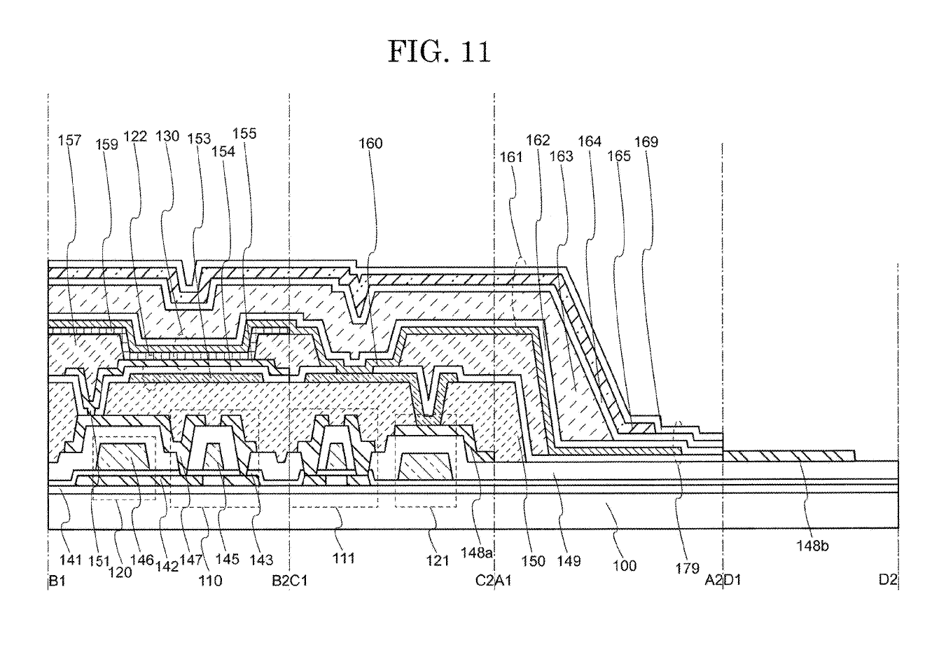

First, as shown in FIG. 11, the inorganic insulating layer 162 is formed on the conductive layer 160 and the insulating layer 149. The inorganic insulating layer 162 may be formed by CVD (plasma CVD or thermal CVD), sputtering, spin-coating, printing or the like. For example, the inorganic insulating layer 162 may be formed of silicon nitride by plasma CVD.

Next, the organic insulating layer 163 is formed on the inorganic insulating layer 162. The organic insulating layer 163 may be formed by vacuum vapor deposition, printing, spin-coating or the like. For example, the organic insulating layer 163 may be formed of acrylic resin by spin-coating. It is preferable that the peripheral region A1-A2 includes a region where the organic insulating layer 163 has been removed.

Next, the inorganic insulating layer 164 is formed on the organic insulating layer 163. The inorganic insulating layer 164 may be formed by substantially the same method as that of the inorganic insulating layer 162. For example, the inorganic insulating layer 164 may be formed of silicon nitride by plasma CVD.

Next, the organic insulating layer 165 is formed on the inorganic insulating layer 164. The organic insulating layer 165 may be formed by substantially the same method as that of the organic insulating layer 163. For example, the organic insulating layer 163 may be formed, by spin-coating, of an acryl resin film containing phenolphthalein and sodium carbonate at 3% by weight in sum with respect to the total weight of the resin film. It is preferable that the peripheral region A1-A2 includes a region where the organic insulating layer 165 has been removed.

Next, the inorganic insulating layer 169 is formed on the organic insulating layer 165 and the inorganic insulating layer 164. The inorganic insulating layer 169 is formed in substantially the same method as that of the inorganic insulating layer 162. For example, the inorganic insulating layer 169 may be formed by stacking silicon oxide and silicon nitride.

The peripheral region A1-A2 includes a region where the insulating layer 150 and the rib 157 have been removed. The insulating layer 154 is formed on a side surface, as well as on an upper surface, of the insulating layer 150 and also on an upper surface of the insulating layer 149. The conductive layer 160 is formed on a side surface, as well as on an upper surface, of the rib 157 and also on an upper surface of the insulating layer 154.

As described above, the peripheral region A1-A2 includes a region in which the insulating layer 150 and the rib 157, which are formed of an organic insulating material, have been removed, and in which the insulating layer 154 and the conductive layer 160, which are formed of an inorganic material, are formed. With such a structure, the insulating layer 150 and the rib 157, which are formed of an organic insulating material, are held between the layers each formed of an inorganic material. This structure prevents permeation of moisture from the peripheral region A1-A2 into the pixel region B1-B2. The combination of the inorganic insulating layer 162, the inorganic insulating layer 164 and the inorganic insulating layer 169 included in the sealing film 161 in an embodiment according to present invention further enhance the moisture blocking effect. Therefore, the above-described region acts as a moisture blocking region 179, and the structure thereof may be considered as a “moisture blocking structure”.

As shown in FIG. 8, the above-described structure may be provided between the display region including the pixel region B1-B2 and the driving circuit region C1-C2, so that the moisture blocking effect is further enhanced.

In the case where the moisture absorption layer 166 is formed on the inorganic insulating layer 169 as shown in FIG. 6 and FIG. 7, the moisture absorption layer 166 may formed by spin-coating, spraying, ink-jetting or the like. For example, the moisture absorption layer 166 may be formed to contain a silicon-containing polymer by spin-coating.

In the case where the gas releasing layer 167 is formed on the moisture absorption layer 166, the gas releasing layer 167 may be formed by spin-coating, spraying, ink-jetting or the like. For example, the gas releasing layer 167 may be formed to contain a thermosetting resin or a thermoplastic resin such as acrylic resin, polyimide resin, epoxy resin or the like by spin-coating.

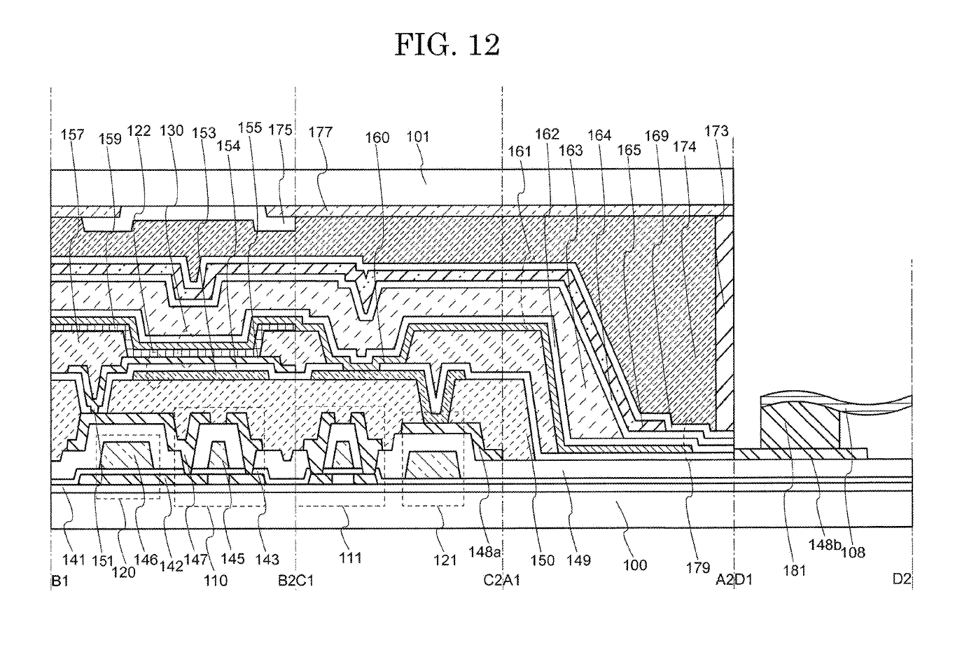

Next, as shown in FIG. 12, on the second substrate 101, the color filter layer 175 and the light blocking layer 177 are formed. Then, the second substrate 101 and the first substrate 100 are bonded together with the sealing member 173 and the filling member 174.

The light blocking layer 177 may be formed by spin-coating, spraying or ink-jetting. The light blocking layer 177 may be formed to have an opening in a region in the pixel region B1-B2 where light from the light emitting element 130 is output. For example, the light blocking layer 177 may be formed of a photosensitive organic resin containing a black pigment (i.e., formed of a black resist) by spin-coating.

The color filter layer 175 is formed, by printing, ink-jetting, etching using photolithography or the like, in the region in the pixel region B1-B2 where the light from the light emitting element 130 is output. In the case where the organic EL layer 159 is formed of different materials on a pixel-by-pixel basis, the color filter layer 175 may not be needed.

Before the first substrate 100 and the second substrate 101 are bonded together with the sealing member 173 and the filling member 174, a spacer or the like may be provided in advance in order to stabilize the distance between the first substrate 100 and the second substrate 101. The spacer may be formed of either an organic insulating material or an inorganic insulating material. In the case where the filling member 174 is formed of a photocurable adhesive, the filling member 174 is cured quickly and thus the work time is shortened.

The flexible printed circuit board 108 may be electrically connected with the conductive layer 148b by use of the anisotropic conductive film 181. At this point, it is preferable that the insulating layers included in the sealing film 161 (i.e., the inorganic insulating layer 162, the organic insulating layer 163, the inorganic insulating layer 164, the organic insulating layer 165, and the inorganic insulating layer 169), the moisture absorption layer 166 and the gas releasing layer 167 may be removed from the terminal region D1-D2 by laser radiation or the like. The anisotropic conductive film 181 may be formed by application of a resin containing metal particles such as silver particles, copper particles or the like.

With manufacturing method in the above-described embodiment, a display device having both of a function of detecting moisture permeation into any part of a display region covered with a sealing film and a sealing performance of a sufficiently high level to prevent permeation of moisture into a light emitting element is manufactured.

The structure, method or the like described in embodiment 3 may be appropriately combined with a structure, method or the like shown in any other embodiment.

1. A display device, comprising:
a first inorganic insulating layer covering a display region;
a first organic insulating layer on the first inorganic insulating layer;
a second inorganic insulating layer on the first organic insulating layer;
a second organic insulating layer on the second inorganic insulating layer; and
a third inorganic insulating layer on the second organic insulating layer;
wherein:
the second organic insulating layer contains a compound reactive with moisture; and
the first organic insulating layer is thicker than the second organic insulating layer.

2. The display device according to claim 1, wherein the second inorganic insulating layer is thinner than the first inorganic insulating layer or the third inorganic insulating layer.

3. The display device according to claim 1, wherein:
the first organic insulating layer has a thickness of 10 μm or greater and less than 100 μm; and
the second organic insulating layer has a thickness of 0.5 μm or greater and less than 10 μm.

4. The display device according to claim 1, wherein the compound is phenolphthalein or sodium carbonate.

5. The display device according to claim 1, further comprising a moisture absorption layer on the third inorganic insulating layer.

6. The display device according to claim 5, wherein the moisture absorption layer contains silicon-containing polymer.

7. The display device according to claim 5, further comprising a gas releasing layer on the moisture absorption layer.

8. The display device according to claim 7, wherein the gas releasing layer contains a thermosetting resin or a thermoplastic resin.

9. The display device according to claim 1, wherein at least one of the first organic insulating layer and the second organic insulating layer has a tapering shape at an edge.

10. The display device according to claim 1, wherein an edge of the first organic insulating layer and an edge of the second organic insulating layer are between an edge of the display region and edges of the first inorganic insulating layer, the second inorganic insulating layer and the third inorganic insulating layer.

11. The display device according to claim 1, further comprising:
an inorganic insulating layer stack region where the first inorganic insulating layer and the second inorganic insulating layer are in direct contact with, and stacked on, each other and the second inorganic insulating layer and the third inorganic insulating layer are in direct contact with, and stacked on, each other is provided outer to the display region;
wherein an edge of the first organic insulating layer and an edge of the second organic insulating layer are between the display region and the inorganic insulating layer stack region.

12. The display device according to claim 1, wherein:
the display region includes a plurality of pixels each including an organic EL element; and
the plurality of pixels are covered with the first inorganic insulating layer, the first organic insulating layer, the second inorganic insulating layer, the second organic insulating layer and the third inorganic insulating layer.

13. A method for manufacturing a display device, the method comprising:
forming a first inorganic insulating layer so as to cover a display region;
forming a first organic insulating layer on the first inorganic insulating layer;
forming a second inorganic insulating layer on the first organic insulating layer;
forming a second organic insulating layer on the second inorganic insulating layer, the second organic insulating layer containing a compound reactive with moisture and being thinner than the first organic insulating layer; and
forming a third inorganic insulating layer on the second organic insulating layer.

14. The method for manufacturing a display device according to claim 13, wherein the second inorganic insulating layer is thinner than the first inorganic insulating layer or the third inorganic insulating layer.

15. The method for manufacturing a display device according to claim 13, wherein the compound contains phenolphthalein or sodium carbonate.

16. The method for manufacturing a display device according to claim 13, further comprising forming a moisture absorption layer on the third inorganic insulating layer.

17. The method for manufacturing a display device according to claim 16, wherein the moisture absorption layer contains silicon-containing polymer.

18. The method for manufacturing a display device according to claim 16, further comprising forming a gas releasing layer on the moisture absorption layer.

19. The method for manufacturing a display device according to claim 18, wherein the gas releasing layer contains a thermosetting resin or a thermoplastic resin.

20. The method for manufacturing a display device according to claim 13, further comprising forming a plurality of pixels each including an organic EL element;
wherein the plurality of pixels are covered with the first inorganic insulating layer, the first organic insulating layer, the second inorganic insulating layer, the second organic insulating layer and the third inorganic insulating layer.
